(19) United States
(12) Patent Application Publication
(10) Pub. No.: US 2025/0006652 A1
(43) Pub. Date: Jan. 2, 2025

(54) FIDUCIALS WITH UNDERLYING DUMMY METALLIZATION FOR INTEGRATED CIRCUIT DEVICE ALIGNMENT

(71) Applicant: Intel Corporation, Santa Clara, CA (US)

(72) Inventors: Omkar G. Karhade, Chandler, AZ (US); Nitin A. Deshpande, Chandler, AZ (US); Francisco Maya, Portland, OR (US); Bhaskar Jyoti Krishnatreya, Hillsboro, OR (US); Tan Nguyen, Hillsboro, OR (US); Siyan Dong, Chandler, AZ (US); Alveera Gill, Hillsboro, OR (US); Keith E. Zawadzki, Portland, OR (US)

(73) Assignee: Intel Corporation, Santa Clara, CA (US)

(21) Appl. No.: 18/346,098

(22) Filed: Jun. 30, 2023

(51) Int. Cl. H01L 23/544; H01L 23/00; H01L 25/065

(52) U.S. Cl. CPC H01L 23/544; H01L 24/33; H01L 25/0657; H01L 2223/54426; H01L 2224/33055; H01L 2224/3313; H01L 2224/3314; H01L 2225/06562; H01L 2924/14

(57) ABSTRACT

An apparatus comprising a first integrated circuit device, the first integrated circuit device comprising a first layer with an area comprising metallization and metal-free slits; and a fiducial in a second layer above the first layer, the fiducial formed over the area comprising the metallization and metal-free slits.

### BACKGROUND

Hybrid bonding interconnect is a packaging technology involving electrical and mechanical connection between two semiconductor devices. In order to bond two semiconductor devices together, surfaces of the devices are brought together under applied pressure and/or at elevated temperature. Hybrid bonding interconnect enables the integration of heterogeneous semiconductor devices (e.g., using different technology nodes or materials) onto a single wafer or package, utilizing various bonding methodologies, such as dielectric-to-dielectric bonding and metal-to-metal bonding.

The devices involved in hybrid bond process may include one or more fiducials (e.g., a structure used for alignment and positioning purposes during the manufacturing and assembly processes). The relative positioning of the fiducials may be detected and used to provide an indication of whether the devices were aligned properly.

### BRIEF DESCRIPTION OF THE DRAWINGS

FIGS. 1A-1B and 2A-2B illustrate example integrated circuit devices comprising fiducials.

FIG. 3 provides a schematic illustration of a cross-sectional view of an example integrated circuit device.

FIG. 4 illustrates diamond fiducial patterns and dummy metallization of integrated circuit devices.

FIG. 5 illustrates circular fiducial patterns and dummy metallization of integrated circuit devices.

FIG. 6 illustrates a process for forming an integrated circuit with fiducials and dummy metallization.

FIG. 7 is a top view of a wafer and dies that may include slit fiducials.

FIG. 8 is a cross-sectional side view of an integrated circuit device that may include slit fiducials.

FIGS. 9A-9D are simplified perspective views of example planar, FinFET, gate-all-around, and stacked gate-all-around transistors.

FIG. 10 is a cross-sectional side view of an integrated circuit device assembly that may include slit fiducials.

FIG. 11 is a block diagram of an example electrical device that may include slit fiducials.

### DETAILED DESCRIPTION

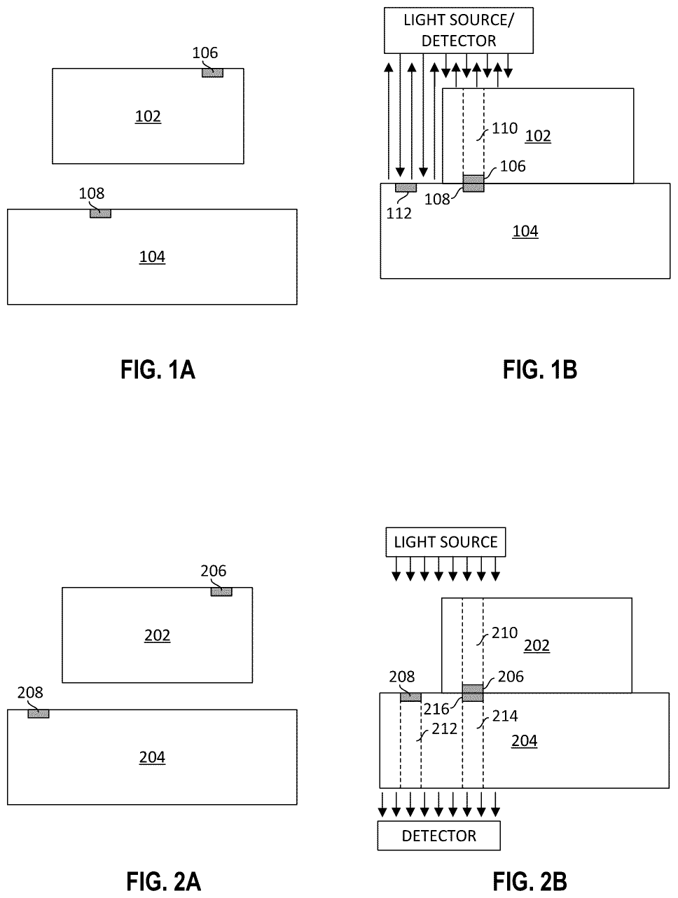

FIGS. 1A-1B illustrate example integrated circuit devices 102 and 104 comprising fiducials 106 and 108. An integrated circuit device may represent any suitable apparatus comprising semiconductor devices, interlayer dielectrics, and metal interconnects, such as a die or a wafer comprising a plurality of dies. The devices may be bonded together as shown in FIG. 1B using a hybrid bonding process.

In some embodiments, hybrid bonding may be performed on a wafer-level (wafer-to-wafer bonding), i.e., individual wafers being hybrid bonded before they are separated into dies. In other embodiments, hybrid bonding may be performed on a die-level (die-to-die bonding), i.e., the dies of individual wafers being hybrid bonded after the wafers have been separated into dies. In yet other embodiments, dies of a wafer may be separated into dies and then hybrid bonded to a wafer before the latter is separated into dies (die-to-wafer bonding).

In various embodiments, devices 102 and 104 may be bonded to one another using a bonding material. In some embodiments, the devices may be heterogenous. For example, they may be fabricated by different manufacturers, using different materials, and/or different manufacturing techniques. For each device, the terms “bottom face” or “back side” of the device may refer to the back of the device, e.g., bottom of the support structure of a given device, while the terms “top face” or “front side” of the device may refer to the opposing other face. When the top face of the first IC device is bonded to the top face of the second IC device (as depicted in FIG. 1B), the devices are described as bonded “face-to-face” (f2f). When the top face of the first IC device is bonded to the bottom face of the second IC device or the bottom face of the first IC device is bonded to the top face of the second IC device, the devices are described as bonded “face-to-back” (f2b). When the bottom face of the first IC device is bonded to the bottom face of the second IC device, the devices are described as bonded “back-to-back” (b2b). The embodiments described herein may be used with any of these bonding types.

In some embodiments, bonding of the faces of the first and second IC devices may be performed using insulator-insulator bonding, e.g., oxide-oxide bonding, where an insulating material of the first IC device is bonded to an insulating material of the second IC device. In some embodiments, a bonding material may be present in between the faces of the first and second IC devices that are bonded together. The bonding material may be applied to one or both faces of the first and second IC devices that should be bonded and then the first and second IC devices are put together, possibly while applying a suitable pressure and heating up the assembly to a suitable temperature. In some embodiments, the bonding process typically takes place at room temperature. The IC devices are subsequently treated at a higher temperature (e.g., in the range or 250 to 450 degrees Celsius to form covalent bonds between the dielectrics and the metal-to-metal bonds between the interconnecting metals. In some embodiments, the bonding material may comprise an adhesive material and/or an etch-stop material. In some embodiments, no bonding material is used, but a bonding interface may still result from the bonding of the first and second IC devices to one another. In some embodiments, other types of bonding may be applied (e.g., metal-metal bonding or other suitable bonding). After bonding, conductive contacts (e.g., bumps) on the first device may be electrically connected to corresponding conductive contacts on the second device.

In hybrid bonding, bump pitches may be much tighter than pitches used in other forms of bonding, e.g., in solder based bonding or C4 bonding. For example, the pitches may be smaller than 10 microns (or even smaller than 1 micron in some cases). Accordingly, alignment accuracy between the dies is critical to ensure proper connectivity between conductive contacts of a first IC device (e.g., die) and conductive contacts of a second IC device (e.g., die).

As depicted in FIG. 1A, fiducials 106, 108, and 112 are formed on or near the front sides of the respective devices. In order to facilitate bonding with high accuracy, the hybrid bonding process may utilize fiducials on the IC devices. Fiducials may also be used during a post bonding inspection process step to measure bond overlay alignment accuracy. The alignment accuracy information may be fed back to the hybrid bonding equipment so that the equipment may make any appropriate adjustments to improve alignment accuracy for other devices as well as fed forward to indicate whether a device is defective based on the bonding results.

In various implementations, alignment metrology uses infrared (IR) light to pass through the device (e.g., through silicon and an inter-layer dielectric (ILD) stack of a die) and compare bonded fiducials in either a reflective or a transmissive mode. FIG. 1B illustrates a reflective mode in which a light source provides IR light which passes down through devices 102 and 104. A portion of this light will be reflected by metal present in devices 102 and 104 (e.g., metal present in fiducials 106, 108, and 112) back to a detector. The detector may use the detected light to identify the position of fiducial 106 on the top device 102 and the position(s) of the fiducials 108 and/or 112 on the base device 104 and determine alignment errors based on a comparison of the positions.

In the embodiment of FIG. 1B, the devices may be considered aligned when fiducial 106 is aligned over fiducial 108 and/or when fiducial 106 is offset from fiducial 112 (e.g., in the x and/or y direction by the proper distances). Thus, in various embodiments, the fiducials (e.g., 106 and 112) can be offset from each other (e.g., in the x and/or y direction) and the alignment is based on how much the position differences between the fiducials vary from the desired offset. FIGS. 2A-2B illustrate other example semiconductor devices 202 and 204 comprising fiducials 206 and 208 that are offset from each other (as well as fiducial 216 that is aligned with fiducial 206). FIG. 2B also illustrates another mode (a transmissive mode) of alignment metrology in which IR light from a light source passes through both devices and is detected on the other side of the devices. The light may pass through metal-free areas and may be at least partially blocked by metallization.

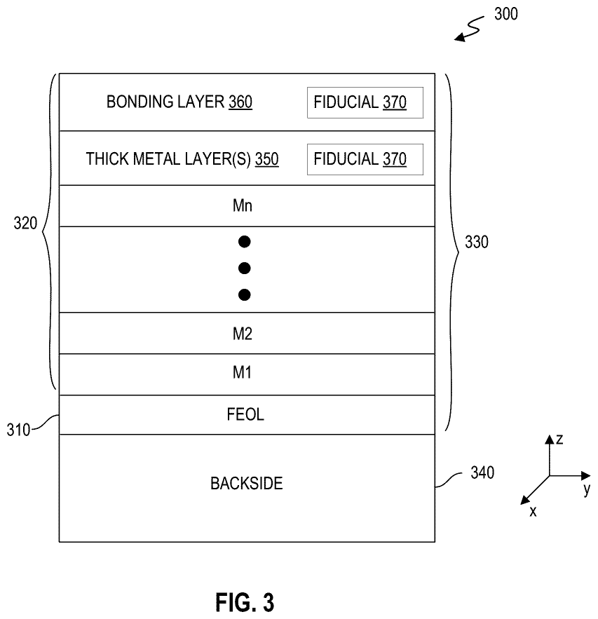

FIG. 3 provides a schematic illustration of a cross-sectional view of an example integrated circuit device (e.g., a die) 300, according to some embodiments of the present disclosure.

Embodiments described herein may include front-end-of-line (FEOL) semiconductor processing and structures. FEOL may be a first portion of IC fabrication where the individual devices (e.g., transistors, capacitors, resistors, etc.) are patterned in the semiconductor substrate or layer. FEOL generally covers everything up to (but not including) the deposition of metal interconnect layers. Following the last FEOL operation, the result is typically a wafer with isolated transistors (e.g., without any wires).

Embodiments described herein may also include back end of line (BEOL) semiconductor processing and structures. BEOL is the second portion of IC fabrication where the individual devices (e.g., transistors, capacitors, resistors, etc.) are interconnected with wiring on the wafer, e.g., the metallization layer or layers. BEOL may include contacts, insulating layers (dielectrics), metal levels, and bonding sites for chip-to-package connections. In the BEOL part of the fabrication stage contacts (pads), interconnect wires, vias and dielectric structures are formed.

Embodiments described herein may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

As shown in FIG. 3, the IC device 300 may include a front side 330 comprising a FEOL portion 310 that includes various logic layers, circuits, and devices to drive and control a logic IC. These circuits and devices may be configured for any number of functions, such as logic or compute transistors, input/output (I/O) transistors, access or switching transistors, and/or radio frequency (RF) transistors, to name a few examples. According to some embodiments, in addition to these devices and circuits, FEOL portion 310 may include, for example, one or more other layers or structures associated with the semiconductor devices and circuits. For example, the FEOL portion 310 can also include a substrate and one or more dielectric layers that surround active and/or conductive portions of the devices and circuits. The FEOL portion may also include one or more conductive contacts that provide electrical contact to transistor elements such as gate structures, drain regions, or source regions. The FEOL portion may also include local interconnect (e.g., vias or lines) that connect contacts to interconnect features within the BEOL portion 320.

The front side 330 of the IC device 300 also includes a BEOL portion 320 including various metal interconnect layers (e.g., metal 1 through metal n, where n is any suitable integer) and thick metal layer(s) 350 comprising one or more metal layers having one or more thickness that are greater than the thicknesses of the lower metal layers (e.g., metal 1 through metal n). Various metal layers of the BEOL portion 320 may be used to interconnect the various inputs and outputs of the FEOL portion 310.

Generally speaking, each of the metal interconnect layers of the BEOL portion 320, e.g., each of the layers M1-Mn and thick metal layer(s) 350 (sometimes referred to as giant metal layers) shown in FIG. 3, may include a via portion and a trench/interconnect portion. Typically, the trench portion of a metal layer is above the via portion, but, in other embodiments, a trench portion may be provided below a via portion of any given metal layer of the BEOL portion 320. The trench portion of a metal layer may be configured for transferring signals and power along metal lines (also sometimes referred to as “trenches”) extending in the x-y plane (e.g., in the x or y directions), while the via portion of a metal layer may be configured for transferring signals and power through metal vias extending in the z-direction, e.g., to any of the adjacent metal layers above or below. Accordingly, vias connect metal structures (e.g., metal lines or vias) from one metal layer to metal structures of an adjacent metal layer. While referred to as “metal” layers, various layers of the BEOL portion 320, e.g., layers M1-Mn or thick metal layer(s) 350 shown in FIG. 3, may include certain patterns of conductive metals, e.g., copper (Cu), aluminum (Al), Tungsten (W), or metal alloys, or more generally, patterns of an electrically conductive material, formed in an insulating medium such as an interlayer dielectric (ILD). The insulating medium may include any suitable ILD materials such as silicon oxide, silicon nitride, silicon carbon nitride, silicon carbide, aluminum oxide, and/or silicon oxynitride. In various embodiments, the insulating medium may have sufficient transparency for IR light (in some embodiments, the IR light may have a wavelength of 1-2 microns) to pass through to facilitate detection of fiducials. In various embodiments, any one or more of these layers may additionally include active devices (e.g., transistors, diodes) and/or passive devices (e.g., capacitors, resistors, inductors).

In various embodiments, a bonding layer 360 may be formed at the top surface of the IC device 300. The bonding layer 360 may include, e.g., various electrical contacts (e.g., bumps, pads, etc.) that may be electrically connected to corresponding electrical contacts of another IC device in a hybrid bonding process. In some embodiments, the bonding layer 360 may also include one or more dielectric materials to create the bonding between the IC devices (e.g., the dielectric material may be placed in between the electrical contacts).

In various embodiments, a fiducial 370 may be placed at or near a surface (e.g., a front side) of an IC device. For example, a fiducial 370 may be placed in the bonding layer 360. Additionally or alternatively, a fiducial 370 may be placed in one or more of the thick metal layer(s) 350. In some embodiments, the same fiducial 370 may be formed in the bonding layer 360 as well as in a thick metal layer 350. In some embodiments, the same fiducial 370 may be formed in multiple layers of the thick metal layer(s) 350. In other embodiments, a fiducial 370 may be formed in another suitable layer near the bonding layer 360 (e.g., one of the other upper metal layers). In some embodiments, a portion of a fiducial may be formed in one layer and another portion of the fiducial may be formed in another layer.

The IC device 300 may also include a back side 340. For example, the back side 340 may formed on the opposite side of a wafer from the front side 330. In various embodiments, the back side 340 may include any suitable elements to assist operation of the IC device 300. For example, the back side 340 may include various metal layers to deliver power to logic of the FEOL portion 310. In some embodiments, transistors or other circuit elements may be formed on the back side 340 of the IC device 300.

In various embodiments, fiducial 370 may include a pattern formed by a metal, such as copper, aluminum, tantalum, or other type of metal (e.g., used in a routing layer). The patterning in the fiducial may have any suitable dimensions. The patterning may be thick enough to reflect and/or block IR light. For example, the patterning may be between 0.025 microns and 5 microns thick. Typical fiducials used in hybrid bonding may be on the order of 30×30 microns to 120×120 microns. If the stack of layers in a device has an interconnect grid of metal underneath a standard fiducial, then the IR light may be blocked by the metal of the grid. Accordingly, a metal free zone in the fiducial footprint underneath the fiducial is preferred for alignment metrology so as not to distort the detection of the fiducial (as used herein a footprint may refer to an area in the x-y plane that can be extended up and/or down in the z-direction). In FIGS. 1 and 2, metal free zones (or low density zones) are bounded by dashed lines and fiducials and are depicted as 110, 210, 212, and 214. In some embodiments, the metal free zone (or low-density metal zone) may persist through the full stack on a device (e.g., as shown by 212 and 214) or only through thicker metals.

In various embodiments, the area underneath the footprint of the fiducial 370 (which may include the layers underneath the fiducial and may be referred to herein as a “zone”) need not be completely metal free in order for sufficient IR light to pass through the layers for alignment metrology purposes. In some embodiments, the area underneath the footprint may be a “low-density metal zone”, such that the density of the metal through the zone is low enough that sufficient IR light passes through for detection of the pattern of the fiducial (and thus could include a no metal zone or a zone with sufficiently low aggregate metal density in the layers). For example, in some low-density metal zones, one or more of the thinnest metal layers (e.g., the lowest metal layers) may be allowed to have a first threshold percentage of metal density (e.g., 20%, 30%, etc.), one or more of the next thinnest metal layers may be allowed to have a second threshold percentage (e.g., 10%, 15%, etc.) of metal density which is lower than the first threshold percentage, and so on (e.g., other thresholds may be employed for other metal layers), while some of the thicker layers (e.g., thick metal layer(s) 350 and/or other higher metal layers underneath the layer(s) with the fiducial) may be required to be metal free within the footprint of the fiducial.

Large metal free zones or low-density metal zones may be problematic. For example, such zones having a large size corresponding to the size of a fiducial (e.g., in the range of 30×30 microns up to 120×120 microns) may create issues during fabrication process steps (e.g., chemical mechanical planarization (CMP) and plating) due to resulting metal density variations across the device.

In various embodiments of the present disclosure, a first IC device may comprise at least one low density metal zone in a layer underneath a layer having a fiducial. The low density metal zone may include a plurality of slits that are metal free. The first IC device may be configured to be bonded to a second IC device that comprises at least one low density metal zone in a layer underneath a layer having a fiducial (where “underneath” may sometimes refer to an orientation before a device is flipped for bonding). The low density metal zone of the second IC device may also include a plurality of slits that are metal free. In various embodiments, the slits of the second IC device are orthogonal (e.g., perpendicular) to the slits of the first IC device, such that if the low density metal zones were combined they would result in an array of small metal free areas. When the IC devices are bonded together, the resulting metal free areas may allow sufficient IR light passage to enable determination of the locations of the fiducials of the IC devices relative to each other.

Various embodiments may provide technical advantages, such as one or more of the following: high fiducial distinction against a metal background, a reduced fiducial footprint, reduced process (e.g., CMP topography, plating) issues, and improved flexibility in fiducial shape.

Various embodiments may provide stacked alignment metrology marks (e.g., fiducials) for hybrid bonding interconnect with dissimilar silicon stack grids. When bonding two chips with dissimilar technologies, the designs may use different global grid sizes (e.g., the grid sizes may be different by a few microns) and the circuitry in the lower metal layers needs to snap to the grid. Thus, even though the fiducials of the different IC devices may be designed to match perfectly, alignment of small metal free zones under the fiducials may be problematic due to the different grid sizes. Various embodiments described herein alleviate this problem since the depopulated areas (the metal free areas) persist regardless of the mismatch in cell sizes and thus the overlay structure does not materially change its optical properties with misalignment.

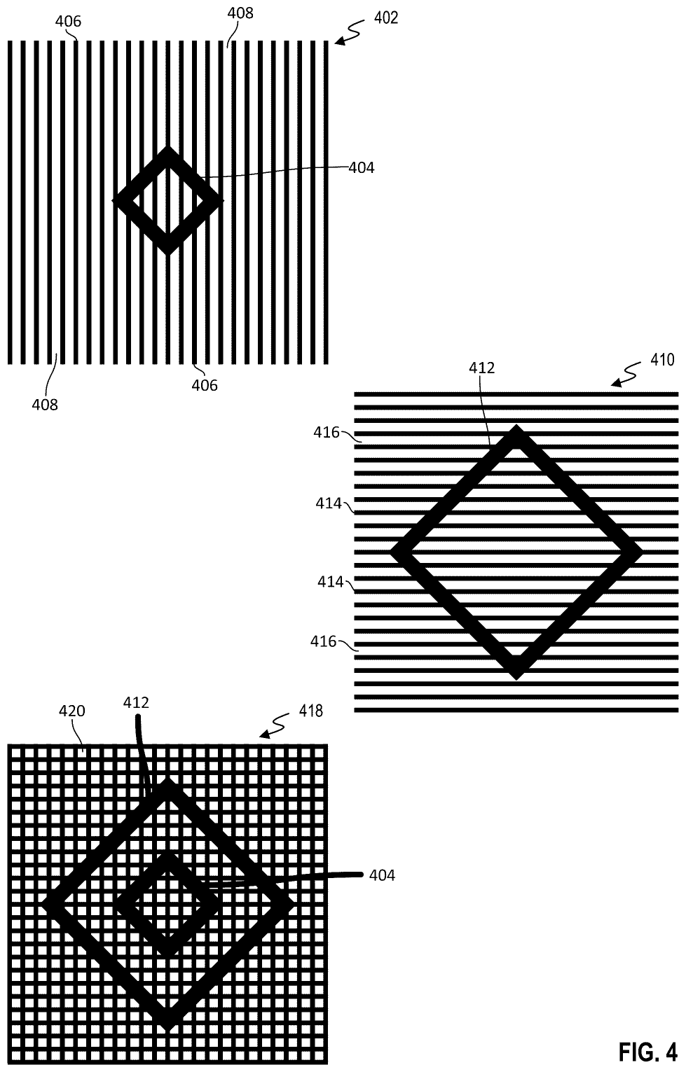

FIG. 4 illustrates diamond fiducial patterns and dummy metallization of integrated circuit devices. Pattern 402 represents a top-down view of a fiducial 404, dummy metallization 406 (e.g., metal that is not connected to other circuitry), and metal-free slits 408 of a first integrated circuit device. Pattern 410 represents a top-down view of a fiducial 412, dummy metallization 414 (e.g., metal that is not connected to other circuitry), and metal-free slits 416 of a second integrated circuit device. Pattern 418 represents the overlay of patterns 402 and 410 (and thus may be roughly representative of the pattern that may be detected responsive to application of IR during alignment metrology despite the dummy metallization and the fiducials being in separate planes).

The fiducial 404 is formed on a layer of the first integrated circuit device that is different from (e.g., above) a layer on which the metallization 406 and metal-free slits 408 are formed. In some embodiments, fiducial 404 may be formed on multiple layers (e.g., the fiducial may be duplicated on multiple layers, such as a bonding layer and a thick metal layer or on two thick metal layers) or may be formed across multiple layers (e.g., a portion of the fiducial may be formed on one layer and another portion of the fiducial may be formed on another layer). Fiducial 412 may be similarly formed on the second integrated circuit device.

The metallization 406 and metal-free slits 408 may be formed on one or more layers that are different from (e.g., below) the layer(s) on or across which the fiducial 404 is formed. For example, the fiducial 404 may be formed on a bonding layer and the metallization 406 and the metal-free slits 408 may be formed on one or more thick metal layers and/or upper metal layers. As another example, the fiducial 404 may be formed on a bonding layer and an upper thick metal layer while the metallization 406 and the metal-free slits 408 may be formed on one or more lower thick metal layers and/or upper thinner metal layers. Metallization 414 and metal-free slits 416 may be similarly formed on the second integrated circuit device.

In the embodiment depicted, the metallization 406 and 414 are thin strips, lines, or segments of metal running across an area of their respective integrated circuit devices. For example, metallization 406 may include strips of metal running lengthwise in an x direction and metallization 414 may include strips of metal running lengthwise in a y direction, or vice versa. In some embodiments, such a design may facilitate compliance with the design rules for the integrated circuit. In other embodiments, the metal strips could run at any suitable angle.

In various embodiments (such as that shown), the strips of metallization 406 are orthogonal (e.g., perpendicular) to the strips of metallization 416. This results in a grid-like pattern of metal-free areas 420 in between respective portions of metallization 406 and metallization 414 (where the metallization 406 and 414 are on different devices and thus at different levels in the z-direction).

In various embodiments (and as shown), the respective strips of dummy metallization (e.g., 406 and/or 414) are parallel to each other and have a common pitch between adjacent strips (such embodiments may help minimize distortion artifacts during alignment metrology). In some embodiments, the pitch between strips of metallization 406 and the pitch between strips of metallization 414 may be the same. In other embodiments, the pitch between strips of metallization 406 and the pitch between strips of metallization 414 may be different (e.g., when the first integrated device and the second integrated device are using different process nodes). In some embodiments, the respective set of strips of metallization 406 and/or 414 could have two or more different pitches between different adjacent pairs of strips.

The strips of metallization 406 and 414 and the metal free slits 408 and 416 may be relatively long and narrow. The width of the strips of metallization 406 and 414 and the metal frec slits 408 and 416 may be chosen appropriately so that they can be fabricated using back end of the line fabrication processes while allowing IR light used for alignment metrology to pass through. In various embodiments, the metal free slits 408 and 416 are wider than the strips of metallization 406 and 414 to allow sufficient IR light passage. In some examples, the strips of metallization 406 and/or 414 may be between 0.5 and 5 microns wide. In particular embodiments, the width of strips of metallization 406 and/or 414 are less than the width of the fiducials 404 and 412. In various embodiments, the width of the fiducials is within the range of 3 to 10 microns, e.g., approximately 5 microns, though any suitable widths are contemplated herein. In various embodiments, the strips of metallization 406 and 414 and the metal free slits 408 and 416 may be much longer than they are wide. For example, a length of a strip or a metal-free slit may be more than 5×, 10×, or 20× the respective width.

In some embodiments, the strips of metallization 406 may have a consistent width and length along the entire area occupied by the strips. In other embodiments, the width of one or more of the strips may vary from the width of one or more other strips. In various embodiments, the strips of metallization 406 have the same width as the strips of metallization 414, though in other embodiments, the strips of metallization 406 may have a width that is different from the width of the strips of metallization 414. Similarly, the lengths of the strips of metallization 406 and 414 may be the same or may be different (and the lengths within a set of strips of metallization 414 or 416 could be consistent or could vary).

The dummy metallization, may comprise any suitable metal such as copper, aluminum, titanium, tantalum, tungsten, or other suitable metal. In some embodiments, the dummy metallization may include a metal that is used for metal interconnects on the same layer as the dummy metallization. The metal-free slits may include, e.g., an ILD material (e.g., silicon dioxide, silicon oxycarbide, silicon carbon nitride, silicon nitride, etc.).

In various embodiments, the fiducials may be shaped with an orientation that is different from the orientation of the dummy metallization 406 and/or 414 (e.g., at least some or the majority of the segments of the fiducials are not parallel to either the metallization 406 and/or 414) to facilitate easier detection of the location of the fiducials during alignment metrology. Such embodiments may allow for various conditions of dummy metal grid densities and thicknesses, which may be present at different transistor technology nodes.

As an example, in the embodiment depicted in FIG. 4, the fiducials 404 and 412 each have the shape of a diamond (e.g., have an outer perimeter with a diamond shape and an inner perimeter with a smaller diamond shape, with the area in between the outer perimeter and inner perimeter filled with metal) The fiducial 404 is configured to nest within the other fiducial 412 concentrically when the first IC device and the second IC device are properly aligned. In various embodiments, the segments of the fiducials have lengths that run at an angle to the metallization 406 and 414. For example, as shown in FIG. 4, the four segments of the diamond shaped fiducial are each angled at 45 degrees relative to both the strips of metallization 406 and the strips of metallization 414.

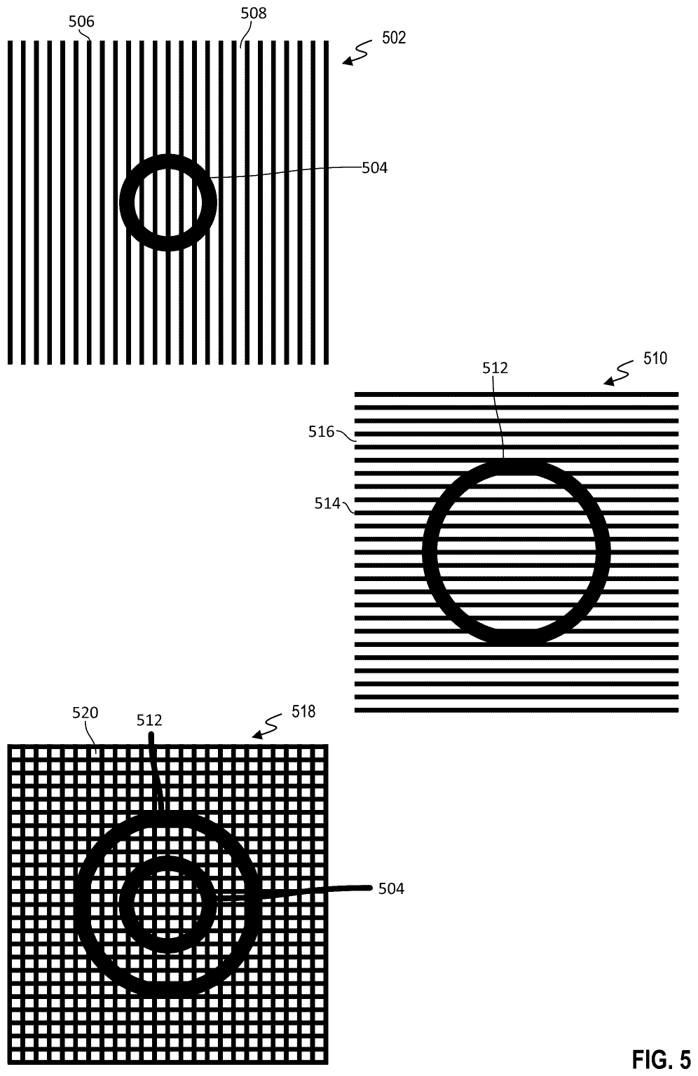

FIG. 5 illustrates a similar configuration to that of FIG. 4, with pattern 502 representing a top-down view of a fiducial 504, metallization 506, and metal-free slits 508 of a first integrated circuit device. Pattern 510 represents a top-down view of a fiducial 512, metallization 514, and metal-free slits 516 of a second integrated circuit device. Pattern 518 represents the overlay of patterns 502 and 510. As another example of fiducials shaped with an orientation that is different from the orientation of the dummy metallization, in this embodiment, the fiducials 504 and 512 have an annular shape (with an outer perimeter in the shape of a circle and an inner perimeter in the shape of a smaller circle), where the fiducial 504 is configured to nest within the other fiducial 512 concentrically when the first IC device and the second IC device are properly aligned.

Other suitable shapes for the fiducial are contemplated herein including any suitable shapes bounded by an inner perimeter and outer perimeter or solid shapes (e.g., shapes that don't have an inner perimeter). Such shapes could include, e.g., rectangles, squares, stars, pentagons, or other suitable shapes.

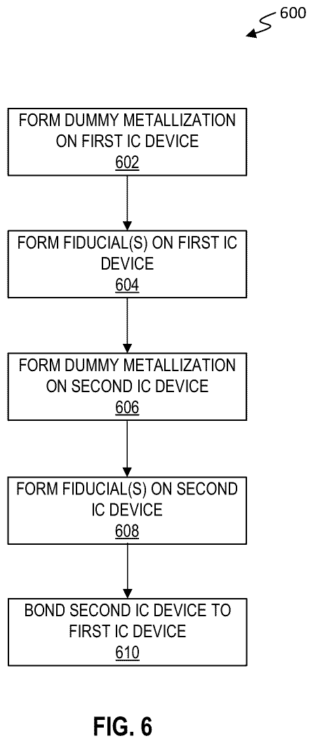

FIG. 6 illustrates a process for forming an integrated circuit with fiducials and dummy metallization. At 602, dummy metallization is formed on a first IC device. The dummy metallization may form metal-free slits through which IR light may pass and may be formed on one or more layers. At 604, one or more fiducials are formed on the first IC device. The fiducial(s) are formed on one or more layers different from (e.g., above) the layer(s) on which the dummy metallization was formed and are formed within the footprint of the dummy metallization.

At 606, dummy metallization is formed on a second IC device. The dummy metallization may form metal-free slits through which IR light may pass and may be formed on one or more layers. In various embodiments, the dummy metallization of the second IC device is formed with lengths extending in a direction that is orthogonal to lengths of the dummy metallization of the first IC device. At 608, one or more fiducials are formed on the second IC device. The fiducial(s) are formed on one or more layers different from (e.g., above) the layer(s) on which the dummy metallization of the second IC device was formed and are formed within the footprint of the dummy metallization. At 610, the second IC device is bonded to the first IC device such that the footprint of the dummy metallization of the first IC device substantially overlaps with the footprint of the dummy metallization of the second IC device.

Although FIG. 6 shows example blocks of process 600, in some implementations, process 600 may include additional blocks, fewer blocks, different blocks, or differently arranged blocks than those depicted in FIG. 6. Additionally, or alternatively, two or more of the blocks of process 600 may be performed in parallel.

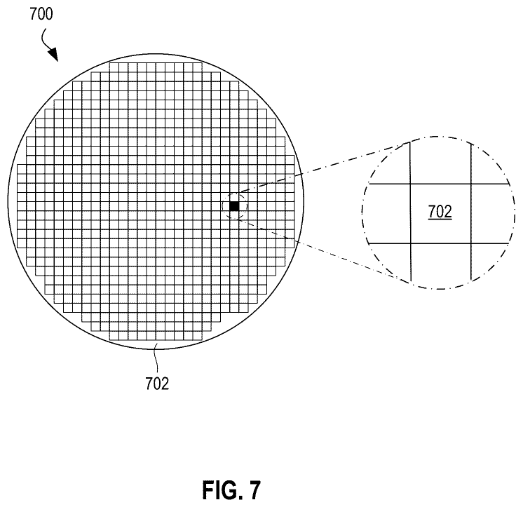

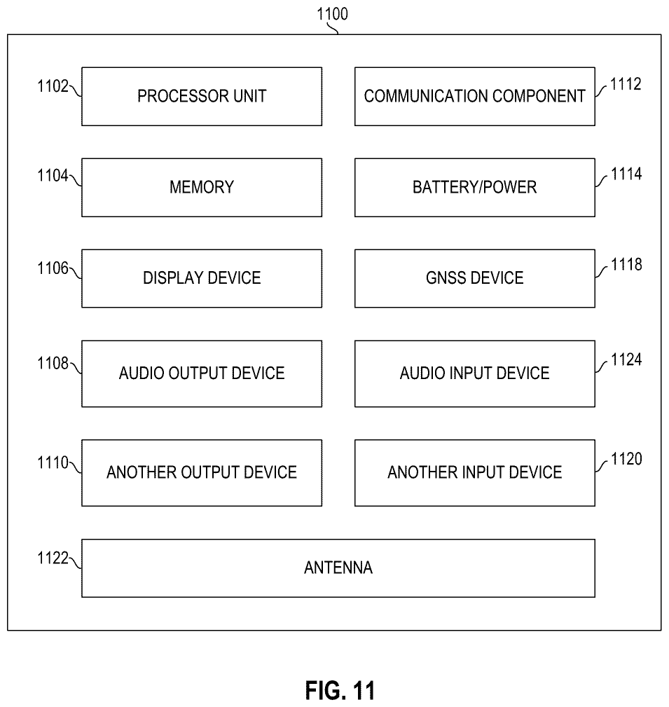

FIG. 7 is a top view of a wafer 700 and dies 702 wherein individual dies may include fiducials with underlying dummy metallization as described herein. The wafer 700 may be composed of semiconductor material and may include one or more dies 702 having integrated circuit structures formed on a surface of the wafer 700. The individual dies 702 may be a repeating unit of an integrated circuit product that includes any suitable integrated circuit. After the fabrication of the semiconductor product is complete, the wafer 700 may undergo a singulation process in which the dies 702 are separated from one another to provide discrete “chips” of the integrated circuit product. The die 702 may include one or more transistors supporting circuitry to route electrical signals to the transistors, passive components (e.g., signal traces, resistors, capacitors, or inductors), and/or any other integrated circuit components. In some embodiments, the wafer 700 or the die 702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 702. For example, a memory array formed by multiple memory devices may be formed on a same die 702 as a processor unit (e.g., the processor unit 1102 of FIG. 11) or other logic that is configured to store information in the memory devices or execute instructions stored in the memory array. Various ones of the microelectronic assemblies disclosed herein may be manufactured using a die-to-wafer assembly technique in which some dies are attached to a wafer 700 that include other dies, and the wafer 700 is subsequently singulated.

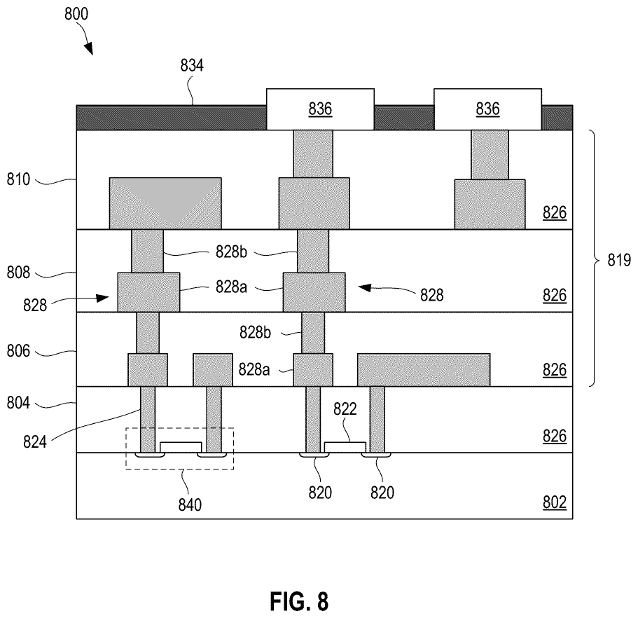

FIG. 8 is a cross-sectional side view of an integrated circuit device 800 that may include fiducials with underlying dummy metallization as described herein. One or more of the integrated circuit devices 800 may be included in one or more dies 702 (FIG. 7). The integrated circuit device 800 may be formed on a die substrate 802 (e.g., the wafer 700 of FIG. 7) and may be included in a die (e.g., the die 702 of FIG. 7). The die substrate 802 may be a semiconductor substrate composed of semiconductor material systems including, for example, n-type or p-type materials systems (or a combination of both). The die substrate 802 may include, for example, a crystalline substrate formed using a bulk silicon or a silicon-on-insulator (SOI) substructure. In some embodiments, the die substrate 802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an integrated circuit device 800 may be used. The die substrate 802 may be part of a singulated die (e.g., the dies 702 of FIG. 7) or a wafer (e.g., the wafer 700 of FIG. 7).

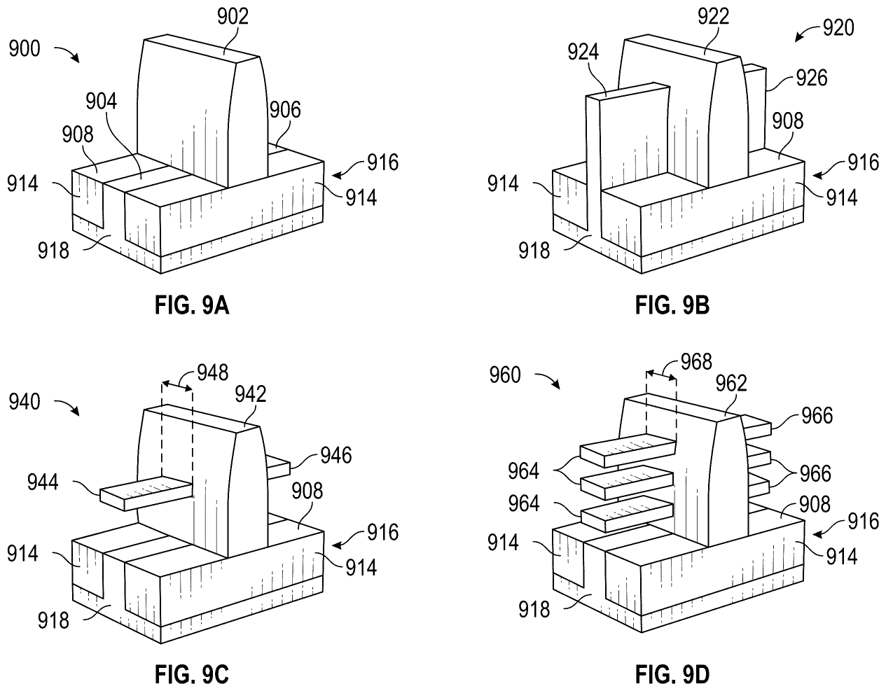

The integrated circuit device 800 may include one or more device layers 804 disposed on the die substrate 802. The device layer 804 may include features of one or more transistors 840 (e.g., metal oxide semiconductor field-effect transistors (MOSFETs)) formed on the die substrate 802. The transistors 840 may include, for example, one or more source and/or drain (S/D) regions 820, a gate 822 to control current flow between the S/D regions 820, and one or more S/D contacts 824 to route electrical signals to/from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors. Examples of non-planar transistors will be described in connection with FIGS. 9A-9D.

A transistor 840 may include a gate 822 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may consist of or comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 840 along the source-channel-drain direction, the gate electrode may consist of or comprise a U-shaped structure that includes a bottom portion substantially parallel to the surface of the die substrate 802 and two sidewall portions that are substantially perpendicular to the top surface of the die substrate 802. In other embodiments, at least one of the metal layers that form the gate electrode may simply be a planar layer that is substantially parallel to the top surface of the die substrate 802 and does not include sidewall portions substantially perpendicular to the top surface of the die substrate 802. In other embodiments, the gate electrode may consist of or comprise a combination of U-shaped structures and planar, non-U-shaped structures. For example, the gate electrode may consist of or comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of individual transistors 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 820 may be formed using one or more alternate semiconductor materials such as germanium or a group III-V material or alloy. In further embodiments, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the integrated circuit device 800.

The interconnect structures 828 (e.g., lines) may be arranged within the interconnect layers 806-810 to route electrical signals according to a wide variety of designs; in particular, the arrangement is not limited to the particular configuration of interconnect structures 828 depicted in FIG. 8. Although a particular number of interconnect layers 806-810 is depicted in FIG. 8, embodiments of the present disclosure include integrated circuit devices having more or fewer interconnect layers than depicted.

In some embodiments, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page and/or in a direction across the page. The vias 828b may be arranged to route electrical signals in a direction of a plane that is substantially perpendicular to the surface of the die substrate 802 upon which the device layer 804 is formed. In some embodiments, the vias 828b may electrically couple lines 828a of different interconnect layers 806-810 together.

The interconnect layers 806-810 may include a dielectric material 826 disposed between the interconnect structures 828, as shown in FIG. 8. In some embodiments, dielectric material 826 disposed between the interconnect structures 828 in different ones of the interconnect layers 806-810 may have different compositions; in other embodiments, the composition of the dielectric material 826 between different interconnect layers 806-810 may be the same. The device layer 804 may include a dielectric material 826 disposed between the transistors 840 and a bottom layer of the metallization stack as well. The dielectric material 826 included in the device layer 804 may have a different composition than the dielectric material 826 included in the interconnect layers 806-810; in other embodiments, the composition of the dielectric material 826 in the device layer 804 may be the same as a dielectric material 826 included in any one of the interconnect layers 806-810.

A first interconnect layer 806 (referred to as Metal 1 or “M1”) may be formed directly on the device layer 804. In some embodiments, the first interconnect layer 806 may include lines 828a and/or vias 828b, as shown. The lines 828a of the first interconnect layer 806 may be coupled with contacts (e.g., the S/D contacts 824) of the device layer 804. The vias 828b of the first interconnect layer 806 may be coupled with the lines 828a of a second interconnect layer 808.

The second interconnect layer 808 (referred to as Metal 2 or “M2”) may be formed directly on the first interconnect layer 806. In some embodiments, the second interconnect layer 808 may include via 828b to couple the interconnect structures 828 of the second interconnect layer 808 with the lines 828a of a third interconnect layer 810. Although the lines 828a and the vias 828b are structurally delineated with a line within individual interconnect layers for the sake of clarity, the lines 828a and the vias 828b may be structurally and/or materially contiguous (e.g., simultaneously filled during a dual-damascene process) in some embodiments.

The third interconnect layer 810 (referred to as Metal 3 or “M3”) (and additional interconnect layers, as desired) may be formed in succession on the second interconnect layer 808 according to similar techniques and configurations described in connection with the second interconnect layer 808 or the first interconnect layer 806. In some embodiments, the interconnect layers that are “higher up” in the metallization stack 819 in the integrated circuit device 800 (e.g., farther away from the device layer 804) may be thicker that the interconnect layers that are lower in the metallization stack 819, with lines 828a and vias 828b in the higher interconnect layers being thicker than those in the lower interconnect layers.

The integrated circuit device 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to external devices. For example, solder bonds may be formed on the one or more conductive contacts 836 to mechanically and/or electrically couple an integrated circuit die including the integrated circuit device 800 with another component (e.g., a printed circuit board). The integrated circuit device 800 may include additional or alternate structures to route the electrical signals from the interconnect layers 806-810; for example, the conductive contacts 836 may include other analogous features (e.g., posts) that route the electrical signals to external components.

In some embodiments in which the integrated circuit device 800 is a double-sided die, the integrated circuit device 800 may include another metallization stack (not shown) on the opposite side of the device layer(s) 804. This metallization stack may include multiple interconnect layers as discussed above with reference to the interconnect layers 806-810, to provide conductive pathways (e.g., including conductive lines and vias) between the device layer(s) 804 and additional conductive contacts (not shown) on the opposite side of the integrated circuit device 800 from the conductive contacts 836.

In other embodiments in which the integrated circuit device 800 is a double-sided die, the integrated circuit device 800 may include one or more through silicon vias (TSVs) through the die substrate 802; these TSVs may make contact with the device layer(s) 804, and may provide conductive pathways between the device layer(s) 804 and additional conductive contacts (not shown) on the opposite side of the integrated circuit device 800 from the conductive contacts 836. In some embodiments. TSVs extending through the substrate can be used for routing power and ground signals from conductive contacts on the opposite side of the integrated circuit device 800 from the conductive contacts 836 to the transistors 840 and any other components integrated into the integrated circuit device (e.g., die) 800, and the metallization stack 819 can be used to route I/O signals from the conductive contacts 836 to transistors 840 and any other components integrated into the integrated circuit device (e.g., die) 800.

Multiple integrated circuit devices 800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIGS. 9A-9D are simplified perspective views of example planar, FinFET, gate-all-around, and stacked gate-all-around transistors. The transistors illustrated in FIGS. 9A-9D are formed on a substrate 916 having a surface 908. Isolation regions 914 separate the source and drain regions of the transistors from other transistors and from a bulk region 918 of the substrate 916.

FIG. 9A is a perspective view of an example planar transistor 900 comprising a gate 902 that controls current flow between a source region 904 and a drain region 906. The transistor 900 is planar in that the source region 904 and the drain region 906 are planar with respect to the substrate surface 908.

FIG. 9B is a perspective view of an example FinFET transistor 920 comprising a gate 922 that controls current flow between a source region 924 and a drain region 926. The transistor 920 is non-planar in that the source region 924 and the drain region 926 comprise “fins” that extend upwards from the substrate surface 908. As the gate 922 encompasses three sides of the semiconductor fin that extends from the source region 924 to the drain region 926, the transistor 920 can be considered a tri-gate transistor. FIG. 9B illustrates one S/D fin extending through the gate 922, but multiple S/D fins can extend through the gate of a FinFET transistor.

FIG. 9C is a perspective view of a gate-all-around (GAA) transistor 940 comprising a gate 942 that controls current flow between a source region 944 and a drain region 946. The transistor 940 is non-planar in that the source region 944 and the drain region 946 are elevated from the substrate surface 908.

FIG. 9D is a perspective view of a GAA transistor 960 comprising a gate 962 that controls current flow between multiple elevated source regions 964 and multiple elevated drain regions 966. The transistor 960 is a stacked GAA transistor as the gate controls the flow of current between multiple elevated S/D regions stacked on top of each other. The transistors 940 and 960 are considered gate-all-around transistors as the gates encompass all sides of the semiconductor portions that extends from the source regions to the drain regions. The transistors 940 and 960 can alternatively be referred to as nanowire, nanosheet, or nanoribbon transistors depending on the width (e.g., widths 948 and 968 of transistors 940 and 960, respectively) of the semiconductor portions extending through the gate.

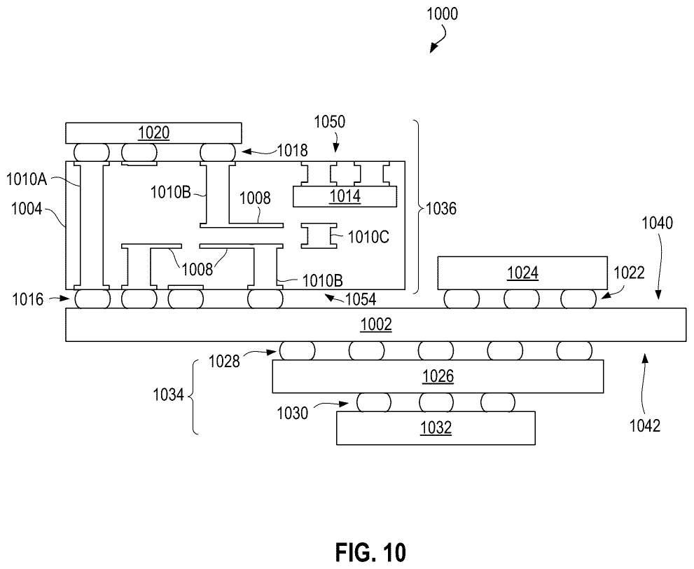

FIG. 10 is a cross-sectional side view of an integrated circuit device assembly 1000 that may include fiducials with underlying dummy metallization as described herein. The integrated circuit device assembly 1000 includes a number of components disposed on a circuit board 1002 (which may be a motherboard, system board, mainboard, etc.). The integrated circuit device assembly 1000 includes components disposed on a first face 1040 of the circuit board 1002 and an opposing second face 1042 of the circuit board 1002; generally, components may be disposed on one or both faces 1040 and 1042.

In some embodiments, the circuit board 1002 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1002. In other embodiments, the circuit board 1002 may be a non-PCB substrate. The integrated circuit device assembly 1000 illustrated in FIG. 10 includes a package-on-interposer structure 1036 coupled to the first face 1040 of the circuit board 1002 by coupling components 1016. The coupling components 1016 may electrically and mechanically couple the package-on-interposer structure 1036 to the circuit board 1002, and may include solder balls (as shown in FIG. 10), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1036 may include an integrated circuit component 1020 coupled to an interposer 1004 by coupling components 1018. The coupling components 1018 may take any suitable form for the application, such as the forms discussed above with reference to the coupling components 1016. Although a single integrated circuit component 1020 is shown in FIG. 10, multiple integrated circuit components may be coupled to the interposer 1004; indeed, additional interposers may be coupled to the interposer 1004. The interposer 1004 may provide an intervening substrate used to bridge the circuit board 1002 and the integrated circuit component 1020.

The integrated circuit component 1020 may be a packaged or unpackaged integrated circuit product that includes one or more integrated circuit dies (e.g., the die 702 of FIG. 7, the integrated circuit device 800 of FIG. 8) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1020, a single monolithic integrated circuit die comprises solder bumps attached to contacts on the die. The solder bumps allow the die to be directly attached to the interposer 1004. The integrated circuit component 1020 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1020 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1020 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1020 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1004 may spread connections to a wider pitch or reroute a connection to a different connection. For example, the interposer 1004 may couple the integrated circuit component 1020 to a set of ball grid array (BGA) conductive contacts of the coupling components 1016 for coupling to the circuit board 1002. In the embodiment illustrated in FIG. 10, the integrated circuit component 1020 and the circuit board 1002 are attached to opposing sides of the interposer 1004; in other embodiments, the integrated circuit component 1020 and the circuit board 1002 may be attached to a same side of the interposer 1004. In some embodiments, three or more components may be interconnected by way of the interposer 1004.

In some embodiments, the interposer 1004 may be formed as a PCB, including multiple metal layers separated from one another by layers of dielectric material and interconnected by electrically conductive vias. In some embodiments, the interposer 1004 may be formed of an epoxy resin, a fiberglass-reinforced epoxy resin, an epoxy resin with inorganic fillers, a ceramic material, or a polymer material such as polyimide. In some embodiments, the interposer 1004 may be formed of alternate rigid or flexible materials that may include the same materials described above for use in a semiconductor substrate, such as silicon, germanium, and other group III-V and group IV materials. The interposer 1004 may include metal interconnects 1008 and vias 1010, including but not limited to through hole vias 1010A (that extend from a first face 1050 of the interposer 1004 to a second face 1054 of the interposer 1004), blind vias 1010B (that extend from the first or second faces 1050 or 1054 of the interposer 1004 to an internal metal layer), and buried vias 1010C (that connect internal metal layers).

In some embodiments, the interposer 1004 can comprise a silicon interposer. Through silicon vias (TSV) extending through the silicon interposer can connect connections on a first face of a silicon interposer to an opposing second face of the silicon interposer. In some embodiments, an interposer 1004 comprising a silicon interposer can further comprise one or more routing layers to route connections on a first face of the interposer 1004 to an opposing second face of the interposer 1004.

The interposer 1004 may further include embedded devices 1014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1004. The package-on-interposer structure 1036 may take the form of any of the package-on-interposer structures known in the art.

The integrated circuit device assembly 1000 may include an integrated circuit component 1024 coupled to the first face 1040 of the circuit board 1002 by coupling components 1022. The coupling components 1022 may take the form of any of the embodiments discussed above with reference to the coupling components 1016, and the integrated circuit component 1024 may take the form of any of the embodiments discussed above with reference to the integrated circuit component 1020.

The integrated circuit device assembly 1000 illustrated in FIG. 10 includes a package-on-package structure 1034 coupled to the second face 1042 of the circuit board 1002 by coupling components 1028. The package-on-package structure 1034 may include an integrated circuit component 1026 and an integrated circuit component 1032 coupled together by coupling components 1030 such that the integrated circuit component 1026 is disposed between the circuit board 1002 and the integrated circuit component 1032. The coupling components 1028 and 1030 may take the form of any of the embodiments of the coupling components 1016 discussed above, and the integrated circuit components 1026 and 1032 may take the form of any of the embodiments of the integrated circuit component 1020 discussed above. The package-on-package structure 1034 may be configured in accordance with any of the package-on-package structures known in the art.

FIG. 11 is a block diagram of an example electrical device 1100 that may include fiducials with underlying dummy metallization as described herein. For example, any suitable ones of the components of the electrical device 1100 may include one or more of the integrated circuit dies 702, integrated circuit devices 800, integrated circuit device assemblies 1000, integrated circuit components 1020, or other components disclosed herein. A number of components are illustrated in FIG. 11 as included in the electrical device 1100, but any one or more of these components may be omitted or duplicated, as suitable for the application. In some embodiments, some or all of the components included in the electrical device 1100 may be attached to one or more motherboards mainboards, or system boards. In some embodiments, one or more of these components are fabricated onto a single system-on-a-chip (SoC) die.

Additionally, in various embodiments, the electrical device 1100 may not include one or more of the components illustrated in FIG. 11, but the electrical device 1100 may include interface circuitry for coupling to the one or more components. For example, the electrical device 1100 may not include a display device 1106, but may include display device interface circuitry (e.g., a connector and driver circuitry) to which a display device 1106 may be coupled. In another set of examples, the electrical device 1100 may not include an audio input device 1124 or an audio output device 1108, but may include audio input or output device interface circuitry (e.g., connectors and supporting circuitry) to which an audio input device 1124 or audio output device 1108 may be coupled.

The electrical device 1100 may include one or more processor units 1102 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1102 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1100 may include a memory 1104, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1104 may include memory that is located on the same integrated circuit die as the processor unit 1102. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1100 can comprise one or more processor units 1102 that are heterogeneous or asymmetric to another processor unit 1102 in the electrical device 1100. There can be a variety of differences between the processing units 1102 in a system in terms of a spectrum of metrics of merit including architectural, microarchitectural, thermal, power consumption characteristics, and the like. These differences can effectively manifest themselves as asymmetry and heterogeneity among the processor units 1102 in the electrical device 1100.

In some embodiments, the electrical device 1100 may include a communication component 1112 (e.g., one or more communication components). For example, the communication component 1112 can manage wireless communications for the transfer of data to and from the electrical device 1100. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1112 may operate in accordance with other wireless protocols in other embodiments. The electrical device 1100 may include an antenna 1122 to facilitate wireless communications and/or to receive other wireless communications (such as amplitude modulation (AM) or frequency modulation (FM) radio transmissions).

In some embodiments, the communication component 1112 may manage wired communications, such as electrical, optical, or any other suitable communication protocols (e.g., IEEE 802.3 Ethernet standards). As noted above, the communication component 1112 may include multiple communication components. For instance, a first communication component 1112 may be dedicated to shorter-range wireless communications such as Wi-Fi or Bluetooth, and a second communication component 1112 may be dedicated to longer-range wireless communications such as global positioning system (GPS), EDGE, GPRS, CDMA, WiMAX, LTE, EV-DO, or others. In some embodiments, a first communication component 1112 may be dedicated to wireless communications, and a second communication component 1112 may be dedicated to wired communications.

The electrical device 1100 may include battery/power circuitry 1114. The battery/power circuitry 1114 may include one or more energy storage devices (e.g., batteries or capacitors) and/or circuitry for coupling components of the electrical device 1100 to an energy source separate from the electrical device 1100 (e.g., AC line power).

The electrical device 1100 may include a display device 1106 (or corresponding interface circuitry, as discussed above). The display device 1106 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1100 may include an audio output device 1108 (or corresponding interface circuitry, as discussed above). The audio output device 1108 may include any embedded or wired or wirelessly connected external device that generates an audible indicator, such speakers, headsets, or earbuds.

The electrical device 1100 may include an audio input device 1124 (or corresponding interface circuitry, as discussed above). The audio input device 1124 may include any embedded or wired or wirelessly connected device that generates a signal representative of a sound, such as microphones, microphone arrays, or digital instruments (e.g., instruments having a musical instrument digital interface (MIDI) output). The electrical device 1100 may include a Global Navigation Satellite System (GNSS) device 1118 (or corresponding interface circuitry, as discussed above), such as a Global Positioning System (GPS) device. The GNSS device 1118 may be in communication with a satellite-based system and may determine a geolocation of the electrical device 1100 based on information received from one or more GNSS satellites, as known in the art.

The electrical device 1100 may include another output device 1110 (or corresponding interface circuitry, as discussed above). Examples of the other output device 1110 may include an audio codec, a video codec, a printer, a wired or wireless transmitter for providing information to other devices, or an additional storage device.

The electrical device 1100 may include another input device 1120 (or corresponding interface circuitry, as discussed above). Examples of the other input device 1120 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1100 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1100 may be any other electronic device that processes data. In some embodiments, the electrical device 1100 may comprise multiple discrete physical components. Given the range of devices that the electrical device 1100 can be manifested as in various embodiments, in some embodiments, the electrical device 1100 can be referred to as a computing device or a computing system.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

It will also be understood that, although the terms “first,” “second,” and so forth may be used herein to describe various elements, these elements should not be limited by these terms. These terms are only used to distinguish one element from another, and are not intended to imply that the objects so described must be in a given sequence, either temporally, spatially, in ranking or in any other manner. For example, a first contact could be termed a second contact, and, similarly, a second contact could be termed a first contact, without departing from the scope of the present example embodiments. The first contact and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. For example, the phrase “A and/or B” means (A), (B), or (A and B), while the phrase “A, B, and/or C” means (A), (B), (C), (A and B), (A and C), (B and C), or (A, B, and C).

As used throughout this description, and in the claims, a list of items joined by the term “at least one of” or “one or more of” can mean any combination of the listed terms.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Furthermore, the terms “comprising,” “including,” “having,” and the like, as used with respect to embodiments of the present disclosure, are synonymous.

The description may use the phrases “in an embodiment,” “according to some embodiments,” “in accordance with embodiments,” or “in embodiments,” which may each refer to one or more of the same or different embodiments.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 10⁷ Siemens per meter (S/m) at 20 degrees Celsius. Examples of such materials include Cu, Ag, Al, Au, W, Zn and Ni.

The term “signal” may refer to at least one current signal, voltage signal, magnetic signal, or data/clock signal.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices.

The description may use perspective-based descriptions such as top/bottom, in/out, over/under, and the like. Such descriptions are merely used to facilitate the discussion and are not intended to restrict the application of embodiments described herein to any particular orientation.

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer means that at least a part of the first material or layer is in direct physical contact with at least a part of that second material/layer. Similar distinctions are to be made in the context of component assemblies.

As used herein, “A is adjacent to B” means that at least part of A is in direct physical contact with at least a part of B.

As used herein, “A is proximate to B” may mean that A is adjacent to B or A is otherwise near to B.

Unless otherwise specified in the specific context of use, the term “predominantly” means more than 50%, or more than half. For example, a composition that is predominantly a first constituent means more than half of the composition (e.g., by volume) is the first constituent (e.g., >50 at. %). The term “primarily” means the most, or greatest, part. For example, a composition that is primarily a first constituent means the composition has more of the first constituent (e.g., by volume) than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

The terms “substantially,” “close,” “approximately,” “near,” and “about,” generally refer to being within +/−10% of a target value (unless specifically specified).

Unless otherwise specified in the explicit context of their use, the terms “substantially equal,” “about equal” or “approximately equal” mean that there is no more than incidental variation between two things so described. In the art, such variation is typically no more than +/−10% of a predetermined target value.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate casier understanding of a circuit or a logical unit. Any represented signal, polarity, current, voltage, etc., as dictated by design needs or preferences, may actually comprise one or more signals that may travel in either direction and may be implemented with any suitable type of signal scheme.

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

Although the figures may illustrate embodiments where structures are substantially aligned to Cartesian axes (e.g., device structures having substantially vertical sidewalls), positive and negative (re-entrant) sloped feature sidewalls often occur in practice. For example, manufacturing non-idealities may cause one or more structural features to have sloped sidewalls. Thus, attributes illustrated are idealized merely for the sake of clearly describing salient features. It is to be understood that schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Example 1 includes an apparatus comprising an integrated circuit device, the integrated circuit device comprising a first layer with an area comprising metallization and metal-free slits; and a fiducial in a second layer above the first layer, the fiducial formed over the area comprising the metallization and metal-free slits.

Example 2 includes the subject matter of Example 1, and wherein the metal-free slits are parallel to each other.

Example 3 includes the subject matter of any of Examples 1 and 2, and wherein the metal-free slits have a common pitch between adjacent metal-free slits.

Example 4 includes the subject matter of any of Examples 1-3, and further including a second integrated circuit device, the second integrated circuit device comprising a third layer with a second area comprising second metallization and second metal-free slits; and a second fiducial formed in a fourth layer different from the third layer, the second fiducial formed within a footprint of the second metallization and second metal-free slits.

Example 5 includes the subject matter of any of Examples 1-4, and wherein the metal-free slits have a length in a first direction, wherein the second metal-free slits have a length in a second direction that is orthogonal to the first direction.

Example 6 includes the subject matter of any of Examples 1-5, and wherein a majority of segments of the fiducial are not parallel to the metal-free slits.

Example 7 includes the subject matter of any of Examples 1-6, and wherein an outer perimeter and an inner perimeter of the fiducial are both diamond shaped.

Example 8 includes the subject matter of any of Examples 1-7, and wherein the fiducial has an annular shape.

Example 9 includes the subject matter of any of Examples 1-8, and wherein a width of the fiducial is greater than a width of a strip of the metallization.

Example 10 includes the subject matter of any of Examples 1-9, and wherein the first layer is a bonding layer of the integrated circuit device.

Example 11 includes the subject matter of any of Examples 1-10, and wherein the second layer is a metal interconnect layer of the integrated circuit device.

Example 12 includes the subject matter of any of Examples 1-11, and wherein the apparatus further comprises a printed circuit board attached to the first integrated circuit device.

Example 13 includes the subject matter of any of Examples 1-12, and further including a second integrated circuit device coupled to the printed circuit board.

Example 14 includes the subject matter of any of Examples 1-13, and wherein the fiducial and the second fiducial have a common shape but different sizes.

Example 15 includes a system comprising a printed circuit board; and a package coupled to the printed circuit board, the package comprising a integrated circuit device comprising dummy metallization on a first layer and metal-free slits between segments of the dummy metallization; and a fiducial on a second layer, wherein the fiducial is within a footprint of the metal-free slits.

Example 16 includes the subject matter of Example 15, and wherein the package further comprises a second integrated circuit device comprising second dummy metallization on a third layer and second metal-free slits between second segments of the second dummy metallization; and a second fiducial on a fourth layer, wherein the second fiducial is within a footprint of the second metal-free slits.

Example 17 includes the subject matter of any of Examples 15 and 16, and wherein the first integrated circuit device is bonded to the second integrated circuit device.

Example 18 includes the subject matter of any of Examples 15-17, and further including a third integrated circuit device coupled to the printed circuit board.

Example 19 includes the subject matter of any of Examples 15-18, and wherein the metal-free slits are parallel to each other.

Example 20 includes the subject matter of any of Examples 15-19, and wherein the metal-free slits have a common pitch between adjacent metal-free slits.

Example 21 includes the subject matter of any of Examples 15-20, and wherein the metal-free slits have a length in a first direction, wherein the second metal-free slits have a length in a second direction that is orthogonal to the first direction.

Example 22 includes the subject matter of any of Examples 15-21, and wherein a majority of segments of the fiducial are not parallel to the metal-free slits.

Example 23 includes the subject matter of any of Examples 15-22, and wherein an outer perimeter and an inner perimeter of the fiducial are both diamond shaped.

Example 24 includes the subject matter of any of Examples 15-23, and wherein the fiducial has an annular shape.

Example 25 includes the subject matter of any of Examples 15-24, and wherein a width of the fiducial is greater than a width of a segment of the metallization.

Example 26 includes the subject matter of any of Examples 15-25, and wherein the first layer is a bonding layer of the integrated circuit device.

Example 27 includes the subject matter of any of Examples 15-26, and wherein the second layer is a metal interconnect layer of the integrated circuit device.

Example 28 includes the subject matter of any of Examples 15-27, and wherein the fiducial and the second fiducial have a common shape but different sizes.

Example 29 includes an apparatus comprising an integrated circuit device, the integrated circuit device comprising a first layer with an area comprising metallization and metal-free slits; and a fiducial in a second layer above the first layer, the fiducial formed over the area comprising the metallization and metal-free slits.

Example 30 includes the subject matter of Example 29, and wherein the metal-free slits are parallel to each other.

Example 31 includes the subject matter of any of Examples 29 and 30, and wherein the metal-free slits have a common pitch between adjacent metal-free slits.

Example 32 includes the subject matter of any of Examples 29-31, and further including a second plurality of metal lines defining a second plurality of metal-free slits on a third layer of a second integrated circuit device; and a second fiducial formed within a footprint of the second plurality of metal-free slits on a fourth layer of the second integrated circuit device, wherein the second plurality of metal-free slits are orthogonal to the plurality of metal-free slits.

Example 33 includes the subject matter of any of Examples 29-32, and wherein the metal-free slits have a length in a first direction, wherein the second metal-free slits have a length in a second direction that is orthogonal to the first direction.

Example 34 includes the subject matter of any of Examples 29-33, and wherein a majority of segments of the fiducial are not parallel to the metal-free slits.

Example 35 includes the subject matter of any of Examples 29-34, and wherein an outer perimeter and an inner perimeter of the fiducial are both diamond shaped.

Example 36 includes the subject matter of any of Examples 29-35, and wherein the fiducial has an annular shape.

Example 37 includes the subject matter of any of Examples 29-36, and wherein a width of the fiducial is greater than a width of a line of the metallization.

Example 38 includes the subject matter of any of Examples 29-37, and wherein the first layer is a bonding layer of the integrated circuit device.

Example 39 includes the subject matter of any of Examples 29-38, and wherein the second layer is a metal interconnect layer of the integrated circuit device.

Example 40 includes the subject matter of any of Examples 29-39, the apparatus further comprising a printed circuit board attached to the integrated circuit device.

Example 41 includes the subject matter of any of Examples 29-40, and further including a second integrated circuit device coupled to the printed circuit board.

Example 42 includes the subject matter of any of Examples 29-41, and wherein the fiducial and the second fiducial have a common shape but different sizes.

Example 43 includes a method comprising forming an integrated circuit device, the forming of the integrated circuit device comprising forming a first layer with an area comprising metallization and metal-free slits; and forming a fiducial in a second layer above the first layer, the fiducial formed over the area comprising the metallization and metal-free slits.

Example 44 includes the subject matter of Example 43, and wherein the metal-free slits are parallel to each other.

Example 45 includes the subject matter of any of Examples 43 and 44, and wherein the metal-free slits have a common pitch between adjacent metal-free slits.

Example 46 includes the subject matter of any of Examples 43-45, and further including forming a second integrated circuit device, the forming the second integrated circuit device comprising forming a third layer with a second area comprising second metallization and second metal-free slits; and forming a second fiducial formed in a fourth layer different from the third layer, the second fiducial formed within a footprint of the second metallization and second metal-free slits.

Example 47 includes the subject matter of any of Examples 43-46, and wherein the metal-free slits have a length in a first direction, wherein the second metal-free slits have a length in a second direction that is orthogonal to the first direction.

Example 48 includes the subject matter of any of Examples 43-47, and wherein a majority of segments of the fiducial are not parallel to the metal-free slits.

Example 49 includes the subject matter of any of Examples 43-48, and wherein an outer perimeter and an inner perimeter of the fiducial are both diamond shaped.

Example 50 includes the subject matter of any of Examples 43-49, and wherein the fiducial has an annular shape.

Example 51 includes the subject matter of any of Examples 43-50, and wherein a width of the fiducial is greater than a width of a strip of the metallization.

Example 52 includes the subject matter of any of Examples 43-51, and wherein the first layer is a bonding layer of the integrated circuit device.

Example 53 includes the subject matter of any of Examples 43-52, and wherein the second layer is a metal interconnect layer of the integrated circuit device.

Example 54 includes the subject matter of any of Examples 43-53, and further including attaching a printed circuit board to the first integrated circuit device.

Example 55 includes the subject matter of any of Examples 43-54, and further including coupling a second integrated circuit device to the printed circuit board.

Example 56 includes the subject matter of any of Examples 43-55, and wherein the fiducial and the second fiducial have a common shape but different sizes.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

1. An apparatus comprising:
an integrated circuit device, the integrated circuit device comprising:
a first layer with an area comprising metallization and metal-free slits; and
a fiducial in a second layer above the first layer, the fiducial formed over the area comprising the metallization and metal-free slits.

2. The apparatus of claim 1, wherein the metal-free slits are parallel to each other.

3. The apparatus of claim 1, wherein the metal-free slits have a common pitch between adjacent metal-free slits.

4. The apparatus of claim 1, further comprising:
a second integrated circuit device, the second integrated circuit device comprising:
a third layer with a second area comprising second metallization and second metal-free slits; and
a second fiducial formed in a fourth layer different from the third layer, the second fiducial formed within a footprint of the second metallization and second metal-free slits.

5. The apparatus of claim 4, wherein the metal-free slits have a length in a first direction, wherein the second metal-free slits have a length in a second direction that is orthogonal to the first direction.

6. The apparatus of claim 1, wherein a majority of segments of the fiducial are not parallel to the metal-free slits.

7. The apparatus of claim 1, wherein an outer perimeter and an inner perimeter of the fiducial are both diamond shaped.

8. The apparatus of claim 1, wherein the fiducial has an annular shape.

9. The apparatus of claim 1, wherein a width of the fiducial is greater than a width of a strip of the metallization.

10. The apparatus of claim 1, wherein the first layer is a bonding layer of the integrated circuit device.

11. The apparatus of claim 10, wherein the second layer is a metal interconnect layer of the integrated circuit device.

12. The apparatus of claim 1, the apparatus further comprising a printed circuit board attached to the first integrated circuit device.

13. The apparatus of claim 12, further comprising a second integrated circuit device coupled to the printed circuit board.

14. A system comprising:
a printed circuit board; and
a package coupled to the printed circuit board, the package comprising a first integrated circuit device comprising:
dummy metallization on a first layer and metal-free slits between segments of the dummy metallization; and
a fiducial on a second layer, wherein the fiducial is within a footprint of the metal-free slits.

15. The system of claim 14, wherein the package further comprises a second integrated circuit device comprising:
second dummy metallization on a third layer and second metal-free slits between second segments of the second dummy metallization; and
a second fiducial on a fourth layer, wherein the second fiducial is within a footprint of the second metal-free slits.

16. The system of claim 15, wherein the first integrated circuit device is bonded to the second integrated circuit device.

17. The system of claim 16, further comprising a third integrated circuit device coupled to the printed circuit board.

18. An apparatus comprising:
a plurality of metal lines defining a plurality of metal-free slits on a layer of an integrated circuit device; and
a fiducial formed within a footprint of the plurality of metal-free slits on a second layer of the integrated circuit device.

19. The apparatus of claim 18, further comprising:
a second plurality of metal lines defining a second plurality of metal-free slits on a third layer of a second integrated circuit device; and
a second fiducial formed within a footprint of the second plurality of metal-free slits on a fourth layer of the second integrated circuit device, wherein the second plurality of metal-free slits are orthogonal to the plurality of metal-free slits.

20. The apparatus of claim 18, wherein the fiducial and the second fiducial have a common shape but different sizes.
